(19) United States
(12) Patent Application Publication
(10) Pub. No.: US 2026/0011562 A1
(43) Pub. Date: Jan. 8, 2026

(54) CHIP MANUFACTURING METHOD

(71) Applicant: DISCO CORPORATION, Tokyo (JP)

(72) Inventors: Yoshinobu SAITO, Tokyo (JP); Mitsuru IKUSHIMA, Tokyo (JP); Yoshikuni MIGIYAMA, Tokyo (JP)

(21) Appl. No.: 19/230,334

(22) Filed: Jun. 6, 2025

(30) Foreign Application Priority Data
Jul. 3, 2024 (JP) 2024-107603
Feb. 19, 2025 (JP) 2025-025037

(51) Int. Cl. H01L 21/304; B23K 26/082; B23K 101/40; H01L 21/683; H01L 21/78

(52) U.S. Cl. CPC H01L 21/304; B23K 26/082; H01L 21/6836; H01L 21/78; B23K 2101/40; H01L 2221/68327; H01L 2221/6834

(57) ABSTRACT

A chip manufacturing method includes: preparing a wafer unit having a protective member fixed to one surface of a wafer and having a recess and a loop-shaped protrusion surrounding the recess on the other surface side of the wafer, the protective member including a first sheet in contact with the wafer, a resin layer stacked on the first sheet, and a second sheet stacked on the resin layer; processing the wafer and the protective member along a boundary between the recess and the loop-shaped protrusion to separate the recess and the loop-shaped protrusion from each other; and after separating of the recess and the loop-shaped protrusion, holding the protective member side of the wafer on a holding table and dividing the wafer from the other surface side to manufacture a plurality of chips.

### CROSS-REFERENCE TO RELATED APPLICATION(S)

The present application claims priority to and incorporates by reference the entire contents of Japanese Patent Application No. 2024-107603 filed in Japan on Jul. 3, 2024 and Japanese Patent Application No. 2025-025037 filed in Japan on Feb. 19, 2025.

### BACKGROUND

The present disclosure relates to a chip manufacturing method.

In order to prevent breakage and warpage of a wafer in a chip manufacturing method in which a wafer is thinned and then divided into a plurality of device chips, there is known a processing method of forming a recess and a loop-shaped protrusion surrounding the recess in a thinning step (refer to JP 2007-019461 A, for example).

In a conventional method applied on two surface sides (one surface side and the other surface side) of a wafer, a thinning step of forming a recess and a loop-shaped protrusion on the other surface side is performed, and after the thinning step, a dicing tape and a frame are fixed to the other surface side, the recess and the loop-shaped protrusion are separated from each other to peel off the loop-shaped protrusion from the dicing tape, and then the wafer is divided into a plurality of device chips from the one surface side in a state where the wafer is supported by the dicing tape and the frame. The presence of large irregularities on the other surface fixed to the dicing tape of the wafer causes a failure in allowing the dicing tape to adhere to the irregularities. This can move the divided chips at the time of division, leading to a possible occurrence of processing defects such as chipping.

### SUMMARY

A chip manufacturing method according to one aspect of the present disclosure includes: preparing a wafer unit, the wafer unit having a protective member fixed to one surface of a wafer and having a recess and a loop-shaped protrusion surrounding the recess provided on the other surface side of the wafer; processing the wafer and the protective member along a boundary between the recess and the loop-shaped protrusion to separate the recess and the loop-shaped protrusion from each other; and after separating of the recess and the loop-shaped protrusion, holding the protective member side of the wafer on a holding table and dividing the wafer from the other surface side to manufacture a plurality of chips.

### BRIEF DESCRIPTION OF THE DRAWINGS

FIG. 1 is a perspective view illustrating an example of a wafer to be processed by a chip manufacturing method according to a first embodiment;

FIG. 2 is a flowchart illustrating a flow of the chip manufacturing method according to the first embodiment;

FIG. 3 is a cross-sectional view illustrating a thinning step included in a preparation step illustrated in FIG. 2;

FIG. 4 is a cross-sectional view illustrating the preparation step illustrated in FIG. 2;

FIG. 5 is a cross-sectional view illustrating the preparation step illustrated in FIG. 2;

FIG. 6 is a cross-sectional view illustrating the preparation step illustrated in FIG. 2;

FIG. 7 is a cross-sectional view illustrating the preparation step illustrated in FIG. 2;

FIG. 8 is a cross-sectional view illustrating one mode of a separation step illustrated in FIG. 2;

FIG. 9 is a cross-sectional view illustrating another mode of the separation step illustrated in FIG. 2;

FIG. 10 is a cross-sectional view illustrating the separation step illustrated in FIG. 2;

FIG. 11 is a cross-sectional view illustrating a division step illustrated in FIG. 2;

FIG. 12 is a cross-sectional view illustrating a preparation step of a chip manufacturing method according to a second embodiment;

FIG. 13 is a cross-sectional view illustrating the preparation step of the chip manufacturing method according to the second embodiment;

FIG. 14 is a cross-sectional view illustrating a thinning step included in the preparation step of the chip manufacturing method according to the second embodiment;

FIG. 15 is a cross-sectional view illustrating a preparation step of the chip manufacturing method according to the second embodiment;

FIG. 16 is a cross-sectional view illustrating a pickup step in the chip manufacturing method according to a first modification;

FIG. 17 is a cross-sectional view illustrating the pickup step in the chip manufacturing method according to the first modification; and

FIG. 18 is a cross-sectional view of a wafer unit prepared in a preparation step of a chip manufacturing method according to a second modification.

### DETAILED DESCRIPTION

Modes (embodiments) for carrying out the present disclosure will be described in detail with reference to the drawings. The present invention is not limited by the description in the following embodiments. In addition, the constituent elements described below include those that can be easily assumed by those skilled in the art and those that are substantially the same. Furthermore, the configurations described below can be appropriately combined with each other. In addition, various omissions, substitutions, or alterations in the configuration can be made without departing from the scope and spirits of the present invention.

### First Embodiment

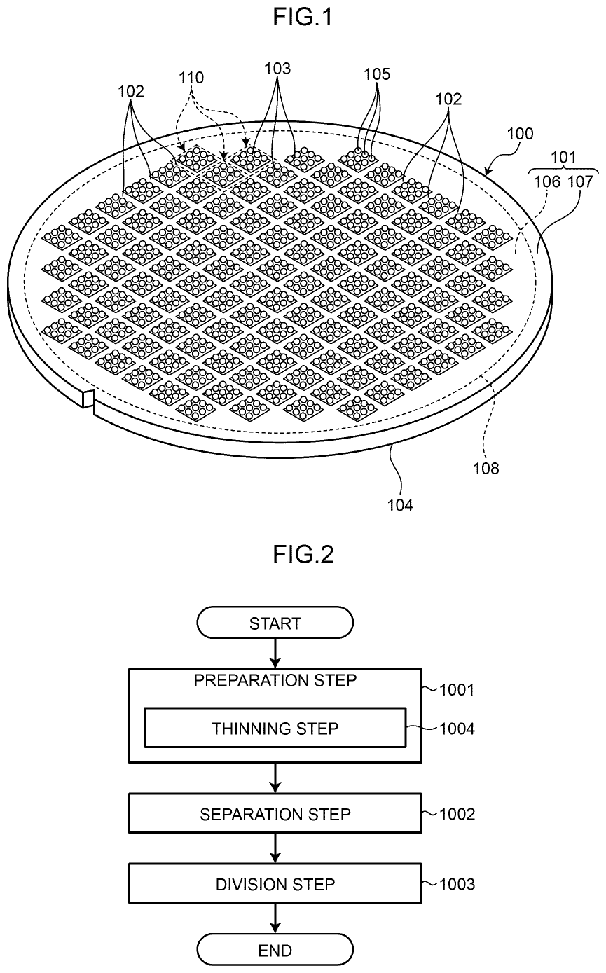

A chip manufacturing method according to a first embodiment of the present disclosure will be described with reference to the drawings. FIG. 1 is a perspective view illustrating an example of a wafer to be processed by the chip manufacturing method according to the first embodiment. FIG. 2 is a flowchart illustrating a flow of the chip manufacturing method according to the first embodiment. The chip manufacturing method according to the first embodiment is a method of processing a wafer 100 illustrated in FIG. 1.

In the first embodiment, the wafer 100 to be processed by the chip manufacturing method according to the first embodiment includes a disk-shaped semiconductor wafer, an optical device wafer, or the like using silicon, sapphire, gallium arsenide, SiC, GaN, lithium tantalate (LT), single crystal diamond, or the like as a substrate.

As illustrated in FIG. 1, the wafer 100 includes, on one surface (front surface) 101, a device region 106 and an outer circumferential margin region 107; the device region 106 being a region having a circular shape in plan view in which a device 103 having a chip shape is formed in each region defined by a plurality of scheduled division lines 102 intersecting (orthogonal to, in the first embodiment) each other; the outer circumferential margin region 107 being a region having no device 103 and formed to have an annular shape in plan view surrounding the device region 106. In addition, the wafer 100 includes a boundary line 108 having a circular shape in plan view, formed between the device region 106 and the outer circumferential margin region 107. The boundary line 108 is a virtual line formed on the one surface 101 of the wafer 100, and thus, is not actually formed on the one surface 101 of the wafer 100.

According to the first embodiment, the wafer 100 has bumps 105 as a plurality of electrodes protruding from the one surface 101 side of the device 103, mounted on the one surface 101 of the device 103. With the presence of the bumps 105 mounted on the one surface 101, the wafer 100 and the device 103 have structures with irregularities. In this manner, due to the presence of the bumps 105, the wafer 100 has irregularities on the one surface 101 side of the device 103. The wafer 100 and the device 103 need not include the bumps 105 in the present disclosure, and may use another mode in which irregularities are formed on the one surface 101 side for other structural reasons. In the wafer 100 and the device 103 in the first embodiment, the other surface (back surface) 104 opposite to the one surface 101 is formed flat. However, the present disclosure is not limited thereto, and a structure with irregularities may be formed on the other surface 104 side.

The wafer 100 illustrated in FIG. 1 is divided along each of the scheduled division lines 102 so as to be divided into individual chips 110. The chip 110 includes: a substrate; and the device 103 formed on the one surface 101 of the substrate.

The chip manufacturing method according to the first embodiment is a method of manufacturing the individual chips 110 by dividing the wafer 100 illustrated in FIG. 1 along each of the scheduled division lines 102. As illustrated in FIG. 2, the chip manufacturing method according to the first embodiment includes a preparation step 1001, a separation step 1002, and a division step 1003. The preparation step 1001 includes a thinning step 1004 in the example of the first embodiment illustrated in FIG. 2. However, the present disclosure is not limited thereto, and may omit the thinning step 1004 as described below.

### Preparation Step

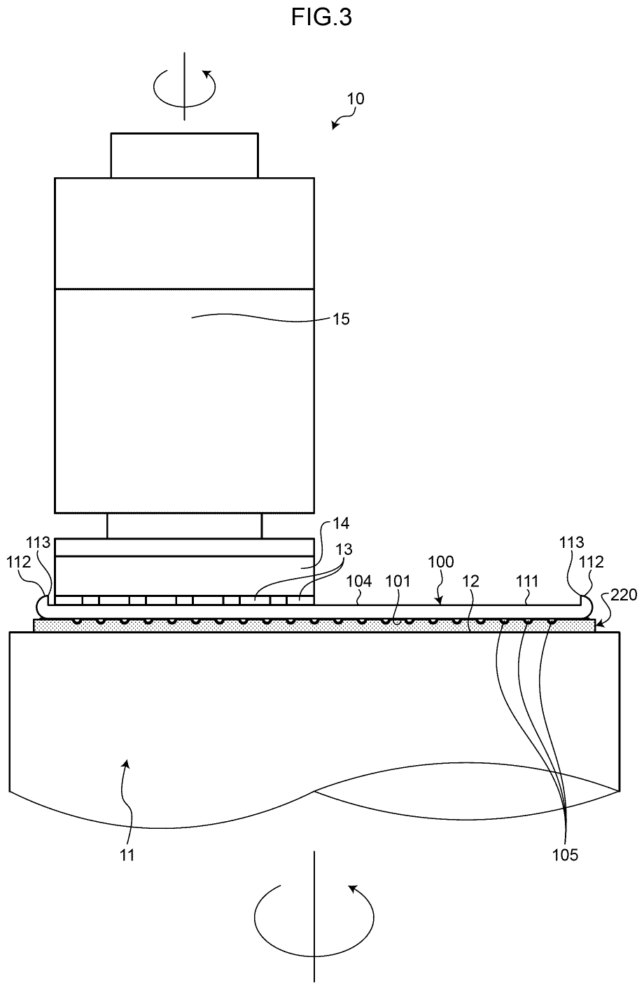

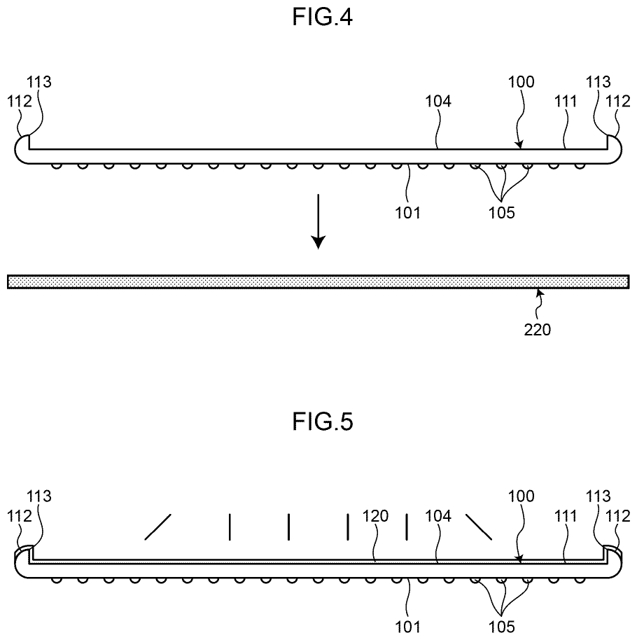

FIG. 3 is a cross-sectional view illustrating the thinning step included in the preparation step illustrated in FIG. 2. FIGS. 4, 5, 6, and 7 are cross-sectional views illustrating the preparation step illustrated in FIG. 2. The preparation step 1001 is a step of preparing a wafer unit 150. The wafer unit 150 has a protective member 200 (illustrated in FIG. 7) fixed to the one surface 101 of the wafer 100, while having a recess 111 and a loop-shaped protrusion 112 surrounding the recess 111 on the other surface 104 side of the wafer 100. The protective member 200 includes a first sheet 201 in contact with the wafer 100, a resin layer 202 stacked on the first sheet 201, and a second sheet 203 stacked on the resin layer 202.

In the first embodiment, the preparation step 1001 first performs a thinning step 1004 of thinning a central region on the other surface 104 side of the wafer 100 to form the recess 111 and the loop-shaped protrusion 112, and then fixes the protective member 200 to the one surface 101 of the wafer 100. Here, the central region on the other surface 104 side of the wafer 100 is a device region 106 or a region wider than the device region 106 in the radial direction. In the first embodiment, the thinning step 1004 is a step of performing processing referred to as TAIKO grinding (registered trademark No. 5297658) in which the other surface 104 side of the device region 106 of the wafer 100 is thinned by a grinder 10 to form the recess 111 and the loop-shaped protrusion 112.

The thinning step 1004 first performs sticking of a backgrinding tape (BG tape) 220 (refer to FIG. 3), having the same diameter as the wafer 100 in plan view, to the one surface 101 side opposite to the other surface 104 being a surface on the grinding side of the wafer 100. In the first embodiment, examples of the BG tape 220 include an adhesive tape obtained by forming a glue layer (adhesive layer) on one surface of a base sheet having a sheet shape, or a thermoplastic resin sheet obtained by forming a base formed of a thermoplastic resin in a sheet shape, with no adhesive layer. The thermoplastic resin sheet is formed with, for example, a polyolefin-based sheet, a polyethylene sheet, a polypropylene sheet, or a polystyrene sheet.

In the thinning step 1004, for example, as illustrated in FIG. 3, the other surface 104 of the device region 106 of the wafer 100 is ground by the grinder 10 to form the recess 111 having a circular shape in plan view on the other surface 104 of the device region 106. As illustrated in FIG. 3, the grinder 10 used in the thinning step 1004 includes: a holding table 11 having a holding surface 12 that sucks and holds the wafer 100; a grinding wheel 14 in which grinding stones 13 are arrayed in a circumferential direction; and a spindle 15 that applies a rotating operation to the grinding wheel 14.

The holding surface 12 is formed on the upper surface of the holding table 11 in parallel with a horizontal plane, and sucks and holds the wafer 100 with a negative pressure introduced by a suction holding mechanism (not illustrated). The holding table 11 includes, at a lower portion on the side opposite to the holding surface 12, a rotation drive unit (not illustrated) that rotates the holding table 11 about a central axis parallel to the vertical direction. The grinding stones 13 are disposed in an annular shape having an outer diameter smaller than that of the wafer 100 in plan view, on the lower surface of the grinding wheel 14. This makes it possible for the grinding wheel 14 to selectively grind a part of the other surface 104 of the wafer 100. The spindle 15 has a rotation axis placed in the vertical direction, and a grinding wheel 14 is attached to a lower end of the spindle 15. The grinding wheel 14 attached to the lower end of the spindle 15 is rotated by the spindle 15 about an axis in the vertical direction.

Specifically, as a first procedure in the thinning step 1004, as illustrated in FIG. 3, the wafer 100 is placed on the holding table 11 with its one surface 101 side to which the BG tape 220 is stuck facing the holding table 11 side. As a next procedure in the thinning step 1004, a negative pressure is introduced onto the holding surface 12, and the wafer 100 is sucked and held by the holding surface 12 of the holding table 11 from the one surface 101 side via the BG tape 220.

Thereafter, the thinning step 1004 causes the rotation drive unit to rotate the holding table 11 sucking and holding the wafer 100 about the central axis parallel to the vertical direction. Subsequently, the thinning step 1004 presses, from above, each grinding stone 13 of the grinding wheel 14 to which the rotating operation has been applied against the other surface 104 of the device region 106 of the wafer 100 sucked and held on the holding table 11 to which the rotating operation has been applied by the spindle 15, thereby grinding the other surface 104 of the device region 106 of the wafer 100. In the thinning step 1004, the recess 111 is formed on the other surface 104 of the device region 106 of the wafer 100 in this manner.

In the thinning step 1004, while the other surface 104 of the device region 106 of the wafer 100 is ground by the grinding stone 13, the other surface 104 of the outer circumferential margin region 107 of the wafer 100 is left without being ground. In this manner, the thinning step 1004 forms the loop-shaped protrusion 112, which protrudes toward the other surface 104 side than the device region 106 and has an annular shape in plan view, on the other surface 104 of the outer circumferential margin region 107 of the wafer 100.

Here, in the thinning step 1004, as in the example of the first embodiment illustrated in FIG. 3, the other surface 104 of a region wider in the radial direction than the device region 106 of the wafer 100 may be ground to form the recess 111 to be wider in the radial direction than the device region 106. Accordingly, the other surface 104 in a region narrower in the radial direction than the outer circumferential margin region 107 may be left without being ground to form the loop-shaped protrusion 112 to be narrower in the radial direction than the outer circumferential margin region 107. Incidentally, when there is a prepared wafer 100 in which the recess 111 and the loop-shaped protrusion 112 are formed by thinning the other surface 104 side, the thinning step 1004 of the preparation step 1001 can be omitted.

In the preparation step 1001, after the thinning step 1004 is performed, as illustrated in FIG. 4, the BG tape 220 is peeled off and removed from the one surface 101 side of the wafer 100 on which the recess 111 and the loop-shaped protrusion 112 are formed by thinning in the thinning step 1004. Thereafter, in the preparation step 1001 in the first embodiment, as illustrated in FIG. 5, a metal film 120 may be formed on the other surface 104 of the wafer 100 on which the recess 111 and the loop-shaped protrusion 112 are formed, from which the BG tape 220 has been peeled off. The formation of the metal film 120 may be omitted in the present disclosure.

Specifically, the preparation step 1001 forms the metal film 120 on the recess 111 and the loop-shaped protrusion 112 on the other surface 104 of the wafer 100 by a sputtering method using a known vacuum film deposition apparatus, for example. In the first embodiment, examples of the metal to constitute the metal film 120 include gold, silver, and titanium. In the first embodiment, the metal film 120 is formed after the BG tape 220 is peeled off and removed in the preparation step 1001, making it possible to suppress the possibility that the BG tape 220 adversely affects the wafer 100 under the environment at the time of forming the metal film 120.

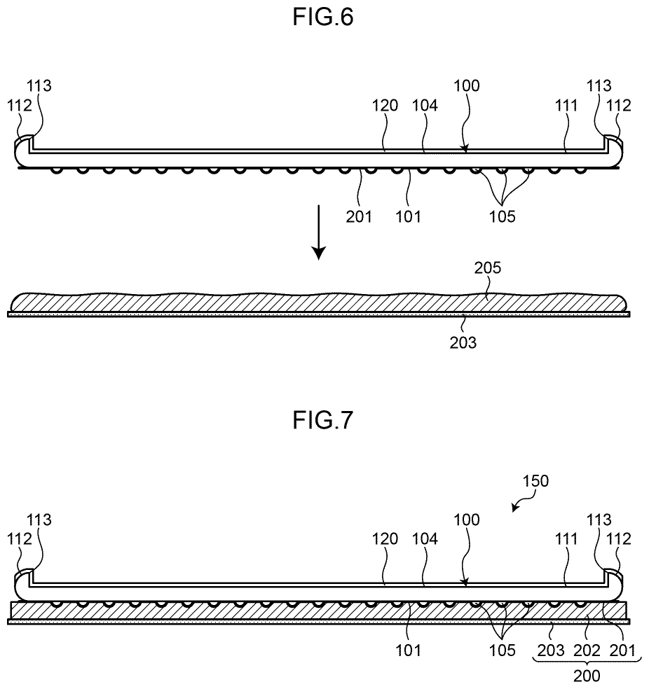

In the preparation step 1001, at least after the BG tape 220 is peeled off and removed, and then, in the first embodiment, after the metal film 120 is further formed, as illustrated in the upper drawing in FIG. 6, the first sheet 201 is stuck and fixed to one surface 101 side of the wafer 100, and a liquid resin 205 is supplied to the surface of the first sheet 201 opposite to the side to which the wafer 100 is stuck and fixed. Here, when a thermoplastic resin sheet is used as the first sheet 201 as described below, the first sheet 201 is stuck and fixed by thermocompression bonding of performing pressing while heating. In the preparation step 1001, in parallel with this operation, the second sheet 203 is placed on a certain support table (not illustrated) having a flat upper surface as illustrated in the lower drawing of FIG. 6, for example, then, the liquid resin 205 is supplied to the upper surface of the second sheet 203, and the wafer 100 to which the first sheet 201 has been fixed is pressed against the liquid resin 205.

Here, the first sheet 201 and the second sheet 203 are both formed of a material substantially transparent to visible light. In the first embodiment, the first sheet 201 is formed by suitably using, for example, a thermoplastic resin sheet obtained by making a base formed of a thermoplastic resin without having a glue layer into a sheet shape having the same shape and size as the wafer 100 in plan view. The thermoplastic resin sheet is formed with, for example, a polyolefin-based sheet, a polyethylene sheet, a polypropylene sheet, or a polystyrene sheet. In the first embodiment, the second sheet 203 is formed by suitably using, for example, a resin sheet not having a glue layer and being formed in the same shape and size as the wafer 100 in plan view. The resin sheet used as the second sheet 203 is formed of polyester such as Poly Ethylene Terephthalate (PET), for example, but is not limited thereto in the present disclosure.

The liquid resin 205 is formed of a material that allows the resin layer 202 formed integrally as described below to be substantially transparent to visible light. In the first embodiment, the liquid resin 205 is suitably formed of an ultraviolet curable resin or a thermosetting resin, for example. The ultraviolet curable resin used as the liquid resin 205 is formed with, for example, a curable resin component such as an ultraviolet curable resin and a binder polymer component such as an acrylic polymer. The thermosetting resin used as the liquid resin 205 is formed with a thermosetting resin component such as an epoxy resin or a phenol resin and a binder polymer component such as an acrylic polymer. The liquid resin 205 may be formed by using a mixture of an ultraviolet curable resin and a thermosetting resin.

Subsequently in the preparation step 1001, as illustrated in FIGS. 6 and 7, the first sheet 201 stuck to the wafer 100 and the second sheet 203 on the support table are overlaid on each other such that the surfaces on the side to which the liquid resin 205 is supplied face each other in the thickness direction. The first sheet 201 and the second sheet 203 are overlaid on each other so as to be substantially aligned with each other without allowing one of the sheets from protruding from the other at ends in plan view with no displacement from each other in a plane direction (radial direction or circumferential direction). This makes a stacked state in which the second sheet 203, the layer of the liquid resin 205, the first sheet 201, and the wafer 100 are stacked in this order from the second sheet 203 side.

In the preparation step 1001, the wafer 100 is further pressed against the support table in this state to cure the liquid resin 205, thereby turning the layer of the liquid resin 205 to be the resin layer 202 (refer to FIG. 7) as an integrated layer. In this manner, the resin layer 202 formed in the preparation step 1001 as described above is a layer formed by pressing and stretching the liquid resin 205 into a layer having substantially the same shape and size as the wafer 100 in plan view and having a uniform thickness, and by curing the layer. Here, the curing of the liquid resin 205 is performed by emitting ultraviolet rays when the liquid resin 205 contains an ultraviolet curable resin, and is performed by heating when the liquid resin 205 contains a thermosetting resin.

In the preparation step 1001, as illustrated in FIG. 7, the first sheet 201, the resin layer 202, and the second sheet 203 are stacked and integrated on the one surface 101 side of the wafer 100 to form the protective member 200. Here, since the first sheet 201, the resin layer 202, and the second sheet 203 are all formed of a material substantially transparent to visible light, the protective member 200 is substantially transparent to visible light. The preparation step 1001 thus forms, as illustrated in FIG. 7, the wafer unit 150 including the wafer 100, the protective member 200 fixed to the one surface 101 side of the wafer 100, and the recess 111 and the loop-shaped protrusion 112 formed on the other surface 104 side of the wafer 100.

### Separation Step

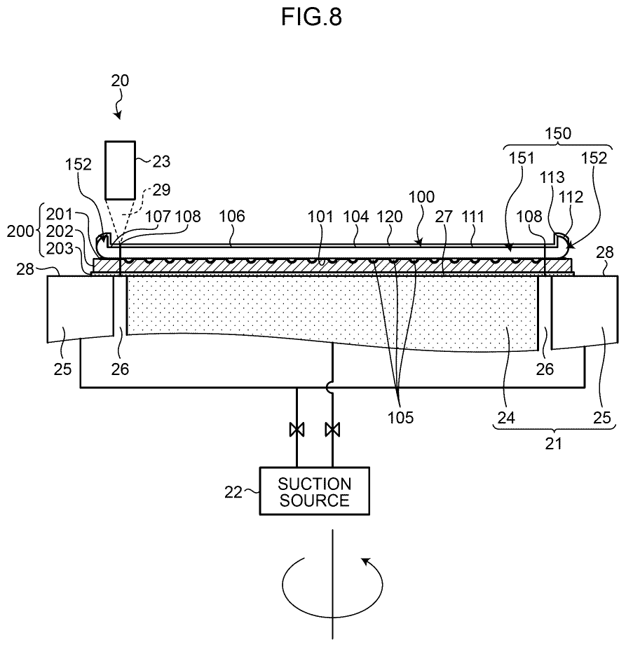

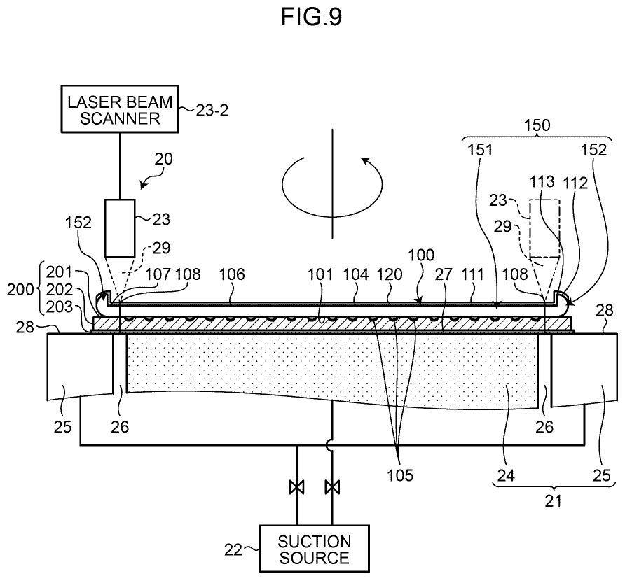

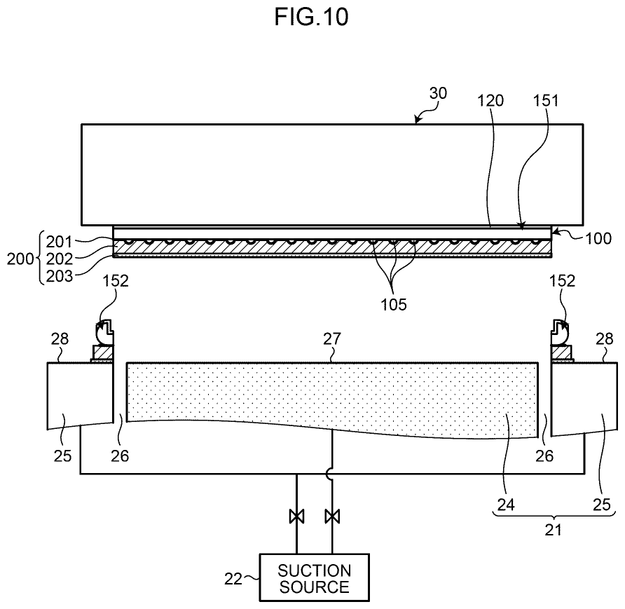

FIG. 8 is a cross-sectional view illustrating one mode of a separation step illustrated in FIG. 2. FIG. 9 is a cross-sectional view illustrating another mode of the separation step illustrated in FIG. 2. FIG. 10 is a cross-sectional view illustrating the separation step illustrated in FIG. 2. As illustrated in FIGS. 8, 9, and 10, the separation step 1002 is a step of processing the wafer 100 and the protective member 200 along a boundary between the recess 111 and the loop-shaped protrusion 112 to separate the recess 111 and the loop-shaped protrusion 112 from each other.

In the separation step 1002, in the first embodiment, as illustrated in FIG. 8, for example, a laser processing device 20 applies a laser beam 29 with a wavelength having absorbency to the wafer 100 and the protective member 200 along a boundary line 113 of a circular shape in a plan view between the recess 111 and the loop-shaped protrusion 112. In the separation step 1002, processing referred to as ablation processing is performed by sublimating or evaporating the wafer 100 and the protective member 200 with the laser beam 29, for example, along the boundary line 113.

As illustrated in FIG. 8, the laser processing device 20 used in the separation step 1002 includes: a holding table 21 that holds the wafer unit 150; a suction holding mechanism 22 provided on the holding table 21; and a laser emission unit 23 that emits a laser beam 29.

As illustrated in FIG. 8, the holding table 21 includes a first holding unit 24, a second holding unit 25, and a gap 26. The first holding unit 24 is formed in a disk shape having the same shape and size as the device region 106 in plan view. An upper surface of the first holding unit 24 is a first holding surface 27 that sucks and holds the wafer unit 150 using the negative pressure introduced by the suction holding mechanism 22. The first holding surface 27 has the same shape and size as the device region 106.

The second holding unit 25 is provided to surround the outer circumference of the first holding unit 24 via the gap 26 having a cylindrical shape, and is formed in an annular plate shape having the same shape and size as the outer circumferential margin region 107 in plan view. An upper surface of the second holding unit 25 is a second holding surface 28 that sucks and holds the wafer unit 150 using the negative pressure introduced by the suction holding mechanism 22. The second holding surface 28 has the same shape and size as the outer circumferential margin region 107. The gap 26 is provided between an outer circumferential surface of the first holding unit 24 and an inner circumferential surface of the second holding unit 25, and is formed in a cylindrical shape.

The holding table 21 includes, at a lower portion on the side opposite to the first holding surface 27 and the second holding surface 28, a rotation drive unit (not illustrated) that rotates the holding table 21 as a whole about a central axis parallel to the vertical direction. The suction holding mechanism 22 includes a mechanism that independently introduces negative pressure onto the first holding surface 27 and the second holding surface 28.

In addition, as illustrated in FIG. 9, the laser processing device 20 used in the separation step 1002 may be changed so as to further include a laser beam scanner 23-2 instead of the rotation drive unit provided on the holding table 21 or together with the rotation drive unit. The laser beam scanner 23-2 is disposed between a laser oscillator and a concentrator of the laser emission unit 23, and changes a traveling direction of the laser beam 29 oscillated from the laser oscillator to a desired direction, thereby changing the emission position of the laser beam 29 to a desired position. This makes it possible for the laser beam scanner 23-2 to scan the laser beam 29 along a desired line.

In the first embodiment, examples of the laser beam scanner 23-2 include a resonant scanner, a galvanometer (galvo) scanner, and an Acousto-Optic Deflector (AOD). For example, when further equipped with a galvanometer (galvo) scanner as the laser beam scanner 23-2, the laser emission unit 23 can function as a galvanometer (galvo) laser that changes or scans the emission position of the laser beam 29.

As a first procedure of the separation step 1002, as illustrated in FIGS. 8 and 9, the wafer unit 150 is placed on the holding table 21 with the protective member 200 side facing the holding table 21. As a next procedure of the separation step 1002, a negative pressure is introduced onto both the first holding surface 27 and the second holding surface 28 by the suction holding mechanism 22, so as to suck and hold the wafer unit 150 from the protective member 200 side by the first holding surface 27 of the first holding unit 24 and the second holding surface 28 of the second holding unit 25. In the separation step 1002 in the mode illustrated in FIG. 8, the wafer unit 150 is placed and sucked and held on the holding table 21 with the center of the wafer unit 150 aligned with the rotation center of the first holding surface 27 of the holding table 21.

In the separation step 1002, after the wafer unit 150 is sucked and held on the holding table 21, the emission position of the laser beam 29 by the laser emission unit 23 is adjusted to a certain position on the boundary line 108 between the device region 106 and the outer circumferential margin region 107 of the wafer unit 150. Subsequently in the separation step 1002, while the laser emission unit 23 emits the laser beam 29, the wafer unit 150 and the emission position of the laser beam 29 are relatively moved along the boundary line 108 to perform ablation processing along the boundary line 108.

In the separation step 1002 in one mode of the first embodiment illustrated in FIG. 8, the emission position of the laser beam 29 is fixed, and the holding table 21 that sucks and holds the wafer unit 150 is rotated by the rotation drive unit, thereby moving the wafer unit 150 and the emission position of the laser beam 29 relative to each other along the boundary line 108. On the other hand, in the separation step 1002 in another mode of the first embodiment illustrated in FIG. 9, the rotation of the holding table 21 is stopped, and the emission position of the laser beam 29 is moved by the laser beam scanner 23-2 along the boundary line 108 of the wafer unit 150 sucked and held on the holding table 21, thereby moving the wafer unit 150 and the emission position of the laser beam 29 relative to each other along the boundary line 108. In the separation step 1002, either the holding table 21 that sucks and holds the wafer unit 150 or the emission position of the laser beam 29 may be rotated or moved, or both of these may be rotated or moved.

In the separation step 1002, using ablation processing along the boundary line 108 like this, the wafer 100 and the protective member 200 of the wafer unit 150 are separated between the device region 106 and the outer circumferential margin region 107. That is, as illustrated in FIGS. 8, 9, and 10, the inner circumferential portion 151 of the wafer unit 150 and the outer circumferential portion 152 of the wafer unit 150 are separated from each other. The inner circumferential portion 151 of the wafer unit 150 is a portion on the inner circumferential side of the device region 106 of the wafer 100 and of the protective member 200 fixed to the device region 106. The outer circumferential portion 152 of the wafer unit 150 is a portion on the outer circumferential side of the outer circumferential margin region 107 of the wafer 100 and of the protective member 200 fixed to the outer circumferential margin region 107.

In the separation step 1002, after separating the wafer 100 and the protective member 200 from each other, the laser beam 29 applied for the ablation processing passes through the gap 26 between the first holding unit 24 (first holding surface 27) and the second holding unit 25 (second holding surface 28), making it possible to suppress the possibility of damaging the holding table 21. The separation step 1002 is not limited to this mode in the present disclosure, and may be performed using a holding table (chuck table) having no gap 26.

In the preparation step 1001, when the recess 111 is formed in the shape and size equivalent to the device region 106 in plan view and the loop-shaped protrusion 112 is formed in the shape and size equivalent to the outer circumferential margin region 107, the boundary line 113 is to be formed in the same shape and size as the boundary line 108 and at positions facing each other in the vertical direction. In this case, by performing ablation processing by emitting the laser beam 29 along the boundary line 108 in the separation step 1002, the wafer 100 of the wafer unit 150 and the protective member 200 can be separated from each other along the boundary line 113.

On the other hand, as in the example of the first embodiment illustrated in FIG. 3, when the recess 111 is formed to be wider in the radial direction than the device region 106 in plan view and the loop-shaped protrusion 112 is formed to be narrower in the radial direction than the outer circumferential margin region 107 in the preparation step 1001, the boundary line 113 is to be formed to be larger in diameter than the boundary line 108 and to be on the outer side in the radial direction. In this case, as illustrated in FIGS. 8 and 9, by performing ablation processing by emitting the laser beam 29 in the circumferential direction on the inner side (recess 111 side) in the radial direction with respect to the boundary line 113 in the separation step 1002, the wafer 100 of the wafer unit 150 and the protective member 200 can be separated from each other along the boundary line 108.

In the separation step 1002, in the example of the first embodiment illustrated in FIGS. 8 and 9, the wafer unit 150 is sucked and held by the holding table 21 from the side of the protective member 200, and the laser beam 29 is emitted from the side of the other surface 104 of the wafer 100 by the laser emission unit 23, but the present disclosure is not limited thereto. Alternatively, in the separation step 1002, the heights of the first holding surface 27 and the second holding surface 28 of the holding table 21 may be varied according to the heights of the recess 111 and the loop-shaped protrusion 112, the wafer unit 150 may be sucked and held by the holding table 21 from the other surface 104 side of the wafer 100, and the laser beam 29 may be emitted from the protective member 200 side by the laser emission unit 23.

In the separation step 1002, after the wafer unit 150 is separated into the inner circumferential portion 151 and the outer circumferential portion 152, as illustrated in FIG. 10, while the suction holding of the second holding surface 28 is maintained by the suction holding mechanism 22, the introduction of the negative pressure to the first holding surface 27 is stopped to cancel the suction holding of the first holding surface 27. In the separation step 1002, the suction holding of the inner circumferential portion 151 is canceled while the suction holding of the outer circumferential portion 152 separated in the separation step 1002 is maintained. Thereafter, in the separation step 1002, as illustrated in FIG. 10, the inner circumferential portion 151 of the wafer unit 150 whose suction holding has been canceled is extracted using chuck and holding from above by a conveyance unit 30, for example, thereby removing the annular (ring-shaped) outer circumferential portion 152 from the wafer unit 150.

Although the separation step 1002 is performed by emission of the laser beam 29 in the first embodiment, the present disclosure is not limited thereto. The wafer unit 150 may be separated into the inner circumferential portion 151 and the outer circumferential portion 152 by performing cutting processing along the boundary line 108 and the boundary line 113 with a cutting blade or the like.

### Division Step

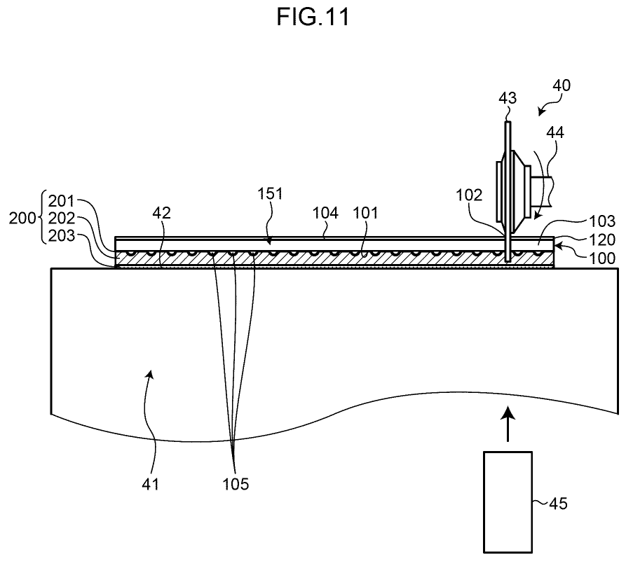

FIG. 11 is a cross-sectional view illustrating a division step illustrated in FIG. 2. The division step 1003 is executed after the separation step 1002. In the division step 1003, as illustrated in FIG. 11, the protective member 200 side of the inner circumferential portion 151 of the wafer unit 150 is held on the holding table 41, and the wafer 100 is divided from the other surface 104 side to manufacture the plurality of chips 110.

In the division step 1003, in the first embodiment, for example, as illustrated in FIG. 11, the wafer 100 in the inner circumferential portion 151 of the wafer unit 150 is cut and divided by a cutting apparatus 40. As illustrated in FIG. 11, the cutting apparatus 40 used in the division step 1003 includes a holding table 41 having a holding surface 42 that sucks and holds the inner circumferential portion 151 of the wafer unit 150, a cutting blade 43, a spindle 44 that applies a rotating operation to the cutting blade 43, and an imaging unit 45.

The holding surface 42 is formed in a region excluding an outer circumferential portion of the upper surface of the holding table 41 so as to be in parallel with a horizontal plane. Using a negative pressure introduced by a suction holding mechanism (not illustrated), the inner circumferential portion 151 of the wafer unit 150 is sucked and held onto the holding surface 42. The holding table 41 includes a holding unit an upper surface of which forms the holding surface 42. The holding unit is formed of a material substantially transparent to visible light, such as soda glass, borosilicate glass, or quartz glass. On an opposite side of the holding surface 42 and lower side of the holding table 41, there is provided a moving mechanism (not illustrated) that moves the holding table 41 in the X-axis direction parallel to the horizontal direction.

The cutting blade 43 is attached to the tip of the spindle 44, and is subjected to a rotating operation by the spindle 44. The spindle 44 is placed in the Y-axis direction whose rotation axis is parallel to the horizontal direction and orthogonal to the X-axis direction, and is equipped with the cutting blade 43 attached to the tip thereof. The spindle 44 rotates the cutting blade 43 attached to the tip about an axis in the Y-axis direction.

The imaging unit 45 includes an imaging element that images the one surface 101 of the wafer 100 in the inner circumferential portion 151 of the wafer unit 150 held on the holding table 41 via the holding table 41 and the protective member 200 which are substantially transparent to visible light. Examples of the imaging element include a charge-coupled device (CCD) imaging element or a complementary MOS (CMOS) imaging element. Below the imaging unit 45, there is provided a moving mechanism (not illustrated) that moves the imaging unit 45 in the horizontal direction. The imaging unit 45 captures an image of one surface 101 of the wafer 100 in the inner circumferential portion 151 of the wafer unit 150 held on the holding table 41 from the holding table 41 side, and acquires an image for performing alignment for aligning the wafer 100 with the cutting blade 43.

Specifically, as a first procedure in the division step 1003, as illustrated in FIG. 11, the inner circumferential portion 151 of the wafer unit 150 extracted by the conveyance unit 30 in the separation step 1002 described above is conveyed onto the holding table 41, so as to be placed on the holding table 41 with the protective member 200 side facing the holding table 41 side. As a next procedure in the division step 1003, a negative pressure is introduced onto the holding surface 42, and the inner circumferential portion 151 of the wafer unit 150 is sucked and held on the holding surface 42 of the holding table 41 from the protective member 200 side. Subsequently in the division step 1003, using the imaging unit 45, alignment processing is performed on the wafer 100 of the inner circumferential portion 151 of the wafer unit 150 sucked and held on the holding surface 42 of the holding table 41.

In the division step 1003, after the alignment processing is performed, the cutting blade 43 that has been subjected to the rotating operation by the spindle 44 is cut into a certain position on the scheduled division line 102 of the wafer 100 of the inner circumferential portion 151 of the wafer unit 150 on the holding table 41, with the cutting to be performed in parallel along the scheduled division line 102 from the other surface 104 exposed upward up to a depth being the thickness of the wafer 100 or more and being less than the thickness of the entire wafer unit 150. In the division step 1003, the cutting blade 43 subjected to the rotating operation is moved relative to the wafer 100 along the scheduled division line 102 of the wafer 100 so as to implement a technique referred to as SAKASA dicing that performs cutting processing of the wafer 100 along the scheduled division line 102 from the other surface 104 side by the cutting blade 43. In a case where the wafer 100 uses SiC as a substrate, performing the SAKASA dicing in the division step 1003 is preferable because the quality (cutting quality) of the chip 110 can be improved as compared with a case where the cutting processing is performed from the one surface 101 side.

In the division step 1003, by performing cutting processing along all of the scheduled division lines 102 in this manner, the wafer 100 of the inner circumferential portion 151 of the wafer unit 150 is divided into the individual chips 110 along each of the scheduled division lines 102 so as to manufacture the plurality of chips 110.

The chip manufacturing method according to the first embodiment having the above-described configuration, sets the wafer 100, in the preparation step 1001, in a state where the protective member 200 including the first sheet 201, the resin layer 202, and the second sheet 203 is fixed to one surface 101, and the recess 111 and the loop-shaped protrusion 112 are formed on the other surface 104 side. Subsequently, in a separation step 1002, the wafer 100 and the protective member 200 are processed along the boundary between the recess 111 and the loop-shaped protrusion 112 to separate the inner circumferential portion 151 on the side where the recess 111 is formed and the outer circumferential portion 152 on the side where the loop-shaped protrusion 112 is formed, from each other.

Therefore, the chip manufacturing method according to the first embodiment has effects, in a case where irregularities are formed in the device 103 due to the presence of the bumps 105 or the like, and the wafer 100 is thinned to form the recess 111 and the loop-shaped protrusion 112 before manufacturing of the chip 110, that the formation of the inner circumferential portion 151 of the wafer unit 150 makes it possible to suppress a decrease in adhesion of the protective member 200 while largely suppressing warpage of the wafer 100, and to facilitate handling of the wafer 100 by the protective member 200.

In a mode of the conventional technique in which the wafer is fixed to the frame via a conventional dicing tape instead of the protective member 200 of the present application, extracting the inner circumferential portion by separating the outer circumferential portion and the frame cannot suppress the warpage of the wafer because only the dicing tape lower, in thickness, than the protective member 200 is stuck to the thinned wafer, leading to a decrease in adhesion of the dicing tape, making it difficult to perform handling in conveyance, etc. Therefore, the conventional division step has been performed by separating the outer circumferential portion 152 from the dicing tape while maintaining the state where the inner circumferential portion 151 of the wafer is fixed to the dicing tape and the frame. In view of this, by forming the protective member 200 having a sufficient thickness, the chip manufacturing method according to the first embodiment has a remarkable operational effect such as suppressing a decrease in adhesion of the protective member 200 while largely suppressing warpage of the wafer 100 even when extracting the inner circumferential portion 151 after separating the outer circumferential portion 152, and facilitating handling in conveyance, etc. by the protective member 200.

Accordingly, the chip manufacturing method according to the first embodiment manufactures the plurality of chips 110 by dividing the portion of the wafer 100 with respect to the inner circumferential portion 151 of the wafer unit 150 formed in this manner, making it possible to suppress the possibility that the device 103 and the chip 110 move at the time of division, leading to suppression of the occurrence of processing defects such as chipping. In this manner, the chip manufacturing method according to the first embodiment has an operational effect of improving the quality of the chip 110 as compared with the conventional techniques.

Further, in the chip manufacturing method according to the first embodiment, the separation step 1002 is performed by emitting the laser beam 29 onto the chip. This makes it possible for the chip manufacturing method according to the first embodiment, to perform high accuracy separation of the inner circumferential portion 151 on the side where the recess 111 is formed and the outer circumferential portion 152 on the side where the loop-shaped protrusion 112 is formed even when it is difficult to separate the protective member 200 by cutting processing due to the thickness or the like.

In the chip manufacturing method according to the first embodiment, after the thinning step 1004 of thinning the central region on the other surface 104 side of the wafer 100 to form the recess 111 and the loop-shaped protrusion 112, the protective member 200 is fixed to the one surface 101 of the wafer 100. Therefore, in the chip manufacturing method according to the first embodiment, the protective member 200 receives impact in the environment in the process of forming the metal film 120 after forming the recess 111 and the loop-shaped protrusion 112, making it possible to suppress the decrease in the adhesion to the wafer 100.

### Second Embodiment

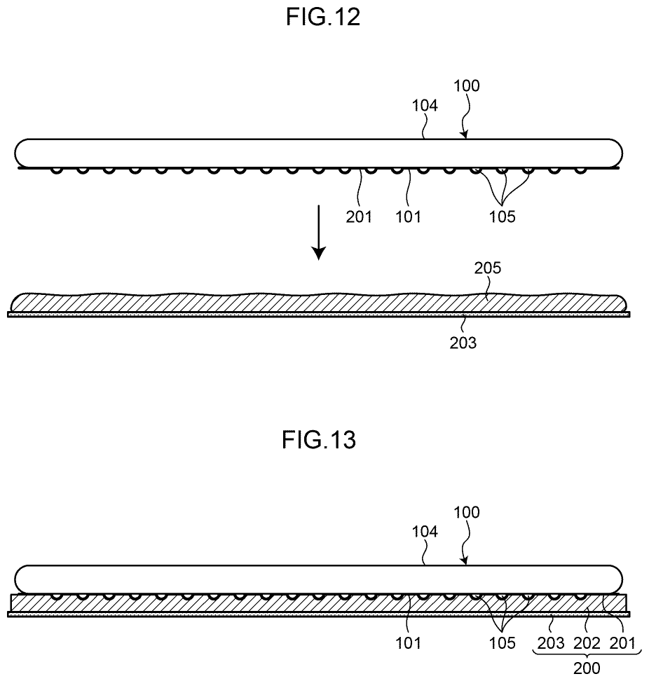

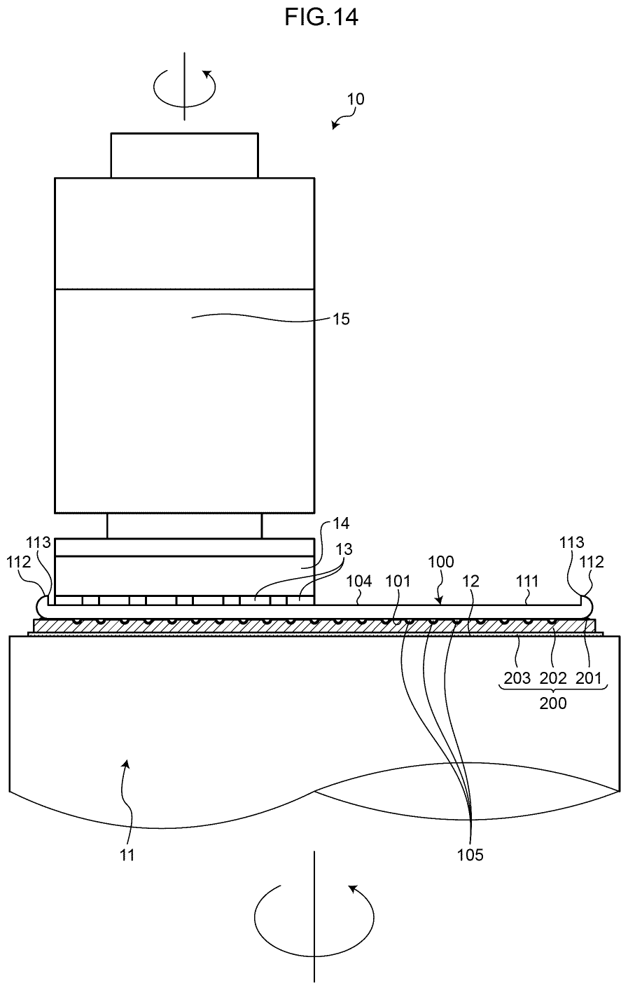

A chip manufacturing method according to a second embodiment of the present disclosure will be described. FIGS. 12, 13 and 15 are cross-sectional views each illustrating a preparation step 1001 of the chip manufacturing method according to the second embodiment. FIG. 14 is a cross-sectional view illustrating the thinning step 1004 included in the preparation step 1001 of the chip manufacturing method according to the second embodiment. In FIGS. 12 to 15, the same portions as those in the first embodiment are denoted by the same reference numerals, and description thereof is omitted.

The chip manufacturing method according to the second embodiment is obtained by modifying the preparation step 1001 in the chip manufacturing method according to the first embodiment, and thus, the other configurations are similar to the first embodiment. In the second embodiment, the preparation step 1001 first performs fixation of the protective member 200 to the one surface 101 of the wafer 100, and thereafter performs the thinning step 1004 of thinning a central region on the other surface 104 side of the wafer 100 to form the recess 111 and the loop-shaped protrusion 112. That is, in the preparation step 1001 of the second embodiment, the order of the thinning step 1004 and the processing of fixing the protective member 200 to the one surface 101 of the wafer 100 is exchanged with respect to the preparation step 1001 of the first embodiment.

In the preparation step 1001 of the second embodiment, before execution of the thinning step 1004, as illustrated in the upper drawing in FIG. 12, the first sheet 201 is stuck and fixed to the one surface 101 side of the wafer 100, and then, liquid resin 205 is supplied to the surface of the first sheet 201 opposite to the side to which the wafer 100 is stuck and fixed. In the preparation step 1001 of the second embodiment, in parallel with this operation, the second sheet 203 is placed on a certain support table (not illustrated) having a flat upper surface as illustrated in the lower drawing of FIG. 12, for example, then, the liquid resin 205 is supplied to the upper surface of the second sheet 203.

Subsequently in the preparation step 1001 of the second embodiment, as illustrated in FIGS. 12 and 13, the first sheet 201 stuck to the wafer 100 and the second sheet 203 on the support table are overlaid on each other such that the surfaces on the side to which the liquid resin 205 is supplied face each other in the thickness direction. This makes a stacked state in which the second sheet 203, the layer of the liquid resin 205, the first sheet 201, and the wafer 100 are stacked in this order from the second sheet 203 side.

In the preparation step 1001 of the second embodiment, the wafer 100 is further pressed against the support table in this state to cure the liquid resin 205, thereby turning the layer of the liquid resin 205 to be the resin layer 202 (refer to FIG. 13) as an integrated layer. In the preparation step 1001 of the second embodiment, as illustrated in FIG. 13, the first sheet 201, the resin layer 202, and the second sheet 203 are stacked and integrated on the one surface 101 side of the wafer 100 to form the protective member 200, thereby fixing the protective member 200 on the one surface 101 of the wafer 100.

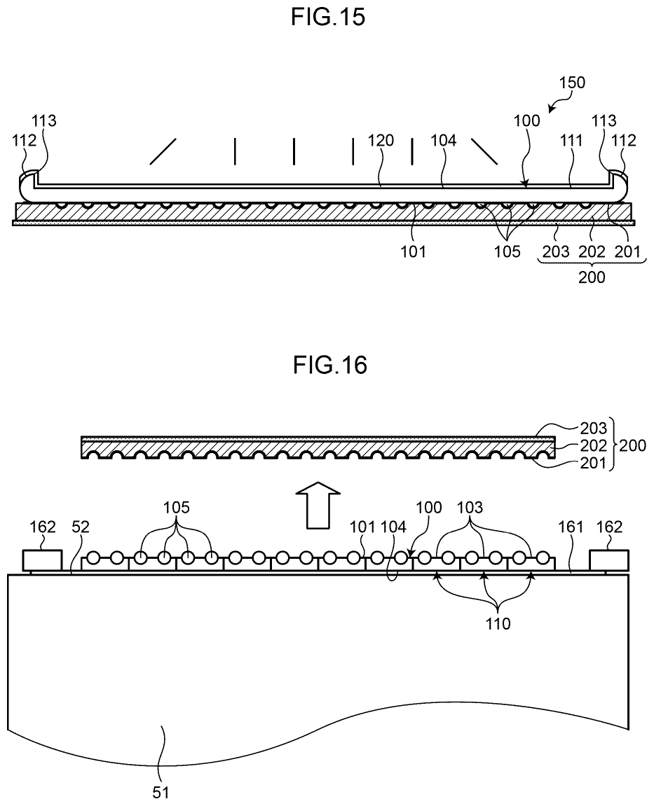

In this manner, in the preparation step 1001 of the second embodiment, after the protective member 200 is fixed to the one surface 101 of the wafer 100, the thinning step 1004 is executed as illustrated in FIG. 14 to form the recess 111 and the loop-shaped protrusion 112 on the other surface 104 side of the wafer 100 in which the protective member 200 is fixed to the one surface 101. Thereafter, in the preparation step 1001 in the second embodiment, as illustrated in FIG. 15, a metal film 120 may be formed on the other surface 104 of the wafer 100 on which the recess 111 and the loop-shaped protrusion 112 are formed similarly to the first embodiment. In the preparation step 1001 of the second embodiment, the wafer unit 150 is formed in this manner.

Similarly to the chip manufacturing method of the first embodiment, the chip manufacturing method according to the second embodiment having the above-described configuration, sets the wafer 100, in the preparation step 1001, in a state where the protective member 200 including the first sheet 201, the resin layer 202, and the second sheet 203 is fixed to one surface 101, and the recess 111 and the loop-shaped protrusion 112 are formed on the other surface 104 side. Subsequently, in a separation step 1002, the wafer 100 and the protective member 200 are processed along the boundary between the recess 111 and the loop-shaped protrusion 112 to separate the inner circumferential portion 151 on the side where the recess 111 is formed and the outer circumferential portion 152 on the side where the loop-shaped protrusion 112 is formed, from each other.

Therefore, similarly to the first embodiment, the chip manufacturing method according to the second embodiment has an operational effect of improving the quality of the chip 110 as compared with the conventional techniques in a case where irregularities due to the presence of the bumps 105 or the like are formed on one surface 101 of the wafer 100, and the wafer 100 is thinned to form the recess 111 and the loop-shaped protrusions 112 on the other surface 104 side and then the chip 110 is manufactured.

In the chip manufacturing method according to the second embodiment, the protective member 200 is fixed to the one surface 101 of the wafer 100 before the thinning step 1004 of thinning the central region on the other surface 104 side of the wafer 100 to form the recess 111 and the loop-shaped protrusion 112. Accordingly, the chip manufacturing method according to the second embodiment can further omit sticking of the BG tape 220 to the one surface 101 of the wafer 100, making it possible to suppress the risk of adhesion of foreign matter or the like caused by the BG tape 220 to the one surface 101 of the device 103 or the bump 105, leading to achievement of highly efficient manufacture of the chip 110.

### First Modification

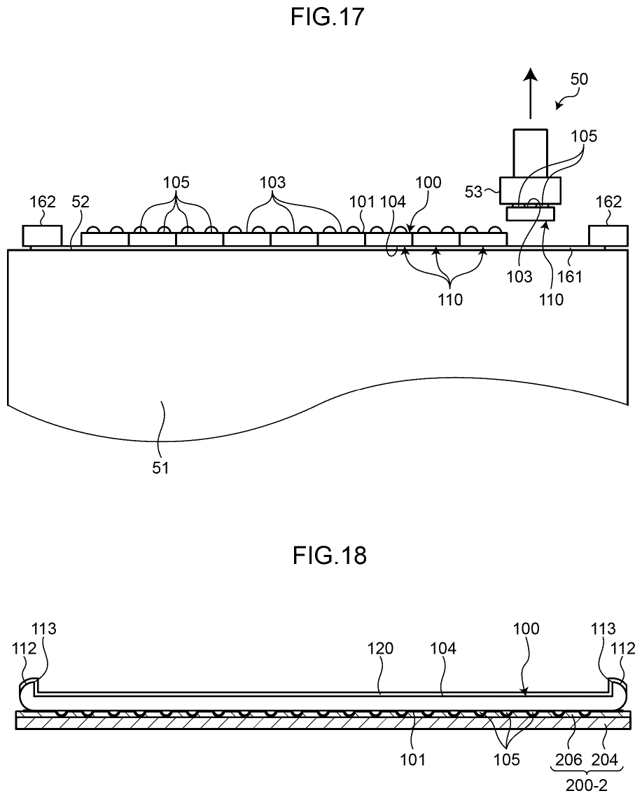

A chip manufacturing method according to a first modification of the first embodiment and the second embodiment of the present disclosure will be described. FIGS. 16 and 17 are cross-sectional views each illustrating a pickup step in the chip manufacturing method according to the first modification. In FIGS. 16 and 17, the same portions as those in the first embodiment and the second embodiment are denoted by the same reference numerals, and description thereof is omitted.

The chip manufacturing method according to the first modification is obtained by adding a pickup step after the division step 1003 of the chip manufacturing method according to the first embodiment and the second embodiment. Accordingly, other configurations are similar to those of the first embodiment and the second embodiment. The pickup step is a step of individually picking up the chips 110 obtained by the division in the division step 1003 and conveying the chips to desired placement positions after the division step 1003 is performed.

In the pickup step, as illustrated in FIGS. 16 and 17, for example, the chips 110 obtained by the division in the division step 1003 are individually picked up by a pickup apparatus 50. As illustrated in FIGS. 16 and 17, the pickup apparatus 50 used in the pickup step includes: a holding table 51 having a holding surface 52 that sucks and holds each of the chips 110; and a chuck holding unit 53 that picks up each of the chips 110 from above using chuck and holding.

In the pickup step, first, as illustrated in FIG. 16, an adhesive tape 161 larger in diameter than the device region 106 of the wafer 100 in plan view is stuck to the other surface 104 side of the plurality of chips 110 obtained by the division in the division step 1003, and a frame 162 having a loop shape is attached to an outer edge of the adhesive tape 161. An example of the adhesive tape 161 includes an adhesive tape obtained by forming a glue layer (adhesive layer) on one surface of a base sheet having a sheet shape.

In the pickup step, after the adhesive tape 161 is stuck to the plurality of chips 110 to attach the frame 162, as illustrated in FIG. 16, the plurality of chips 110 is placed on the holding table 51 with the side of the other surface 104 to which the adhesive tape 161 is stuck facing the holding table 51 side. In the pickup step, next, a negative pressure is introduced onto the holding surface 52, and the plurality of chips 110 is sucked and held by the holding surface 52 of the holding table 51 from the other surface 104 side via the adhesive tape 161. Thereafter, as illustrated in FIG. 16, the pickup step causes the protective member 200 to be peeled off and removed from the one surface 101 side of the plurality of chips 110.

In the pickup step, after the protective member 200 is peeled off and removed, as illustrated in FIG. 17, each of the chips 110 is picked up one by one sequentially from above using chuck and holding by the chuck holding unit 53.

In the chip manufacturing method according to the first modification having the above configuration, the chips 110 having an improved quality can be suitably and sequentially picked up one by one by the pickup step and conveyed to a desired placement position.

### Second Modification

A chip manufacturing method according to a second modification of the first embodiment and the second embodiment of the present disclosure will be described. FIG. 18 is a cross-sectional view of a wafer unit prepared in a preparation step of a chip manufacturing method according to the second modification. In FIG. 18, the same portions as those in the first embodiment and the second embodiment are denoted by the same reference numerals, and description thereof is omitted.

The second modification is the same as the first embodiment and the second embodiment except for including a protective member 200-2 as a variation. In the second modification, as illustrated in FIG. 18, the protective member 200-2 is a tape having a thickness capable of sufficiently absorbing the thickness of the irregularities such as the bump 105 formed on one surface 101. In the example illustrated in FIG. 18, the protective member 200-2 is a tape including: a base layer 204 formed of a non-adhesive resin; and a glue layer 206 stacked on the base layer 204 and formed of an adhesive resin.

The protective member 200-2 illustrated in FIG. 18 buries the bump 105 in the glue layer 206 to absorb the thickness of the irregularities formed on the one surface 101. That is, the protective member 200-2 according to the second modification is particularly a tape in which the thickness of the glue layer 206 exceeds the amount of protrusion of the bump 105 from the one surface 101. In the present disclosure, instead of a tape having the base layer 204 and the glue layer 206, the protective member 200-2 may be a tape having a thickness larger than the amount of protrusion of the bump 105 from the one surface 101 and formed of a thermoplastic resin without the glue layer 206. When the protective member 200-2 is a tape formed of a thermoplastic resin without the glue layer 206, the protective member 200-2 is fixed to the wafer 100 by thermocompression bonding.

In the chip manufacturing method according to the second modification having the above configuration, similarly to the first embodiment and the second embodiment, the preparation step 1001 is used to fix the protective member 200 to one surface 101 of the wafer 100 and form the recess 111 and the loop-shaped protrusion 112 on the other surface 104 side, and the separation step 1002 is used to separate the wafer 100 into the inner circumferential portion 151 on the side where the recess 111 is formed and the outer circumferential portion 152 on the side where the loop-shaped protrusion 112 is formed.

Therefore, similarly to the first embodiment and the second embodiment, the chip manufacturing method according to the second modification has an operational effect of improving the quality of the chip 110 as compared with the conventional techniques in a case where irregularities due to the presence of the bumps 105 or the like are formed on one surface 101 of the wafer 100, and the wafer 100 is thinned to form the recess 111 and the loop-shaped protrusions 112 on the other surface 104 side and then the chip 110 is manufactured.

In the first embodiment and the second embodiment described above, the protective member 200 is divided together with the wafer 100 in the separation step 1002. However, the present disclosure may set the separation step 1002 in which the wafer 100 is divided and the protective member 200 is not divided.

According to the present disclosure, in a case where large irregularities are formed on one surface of a wafer, and the wafer is thinned to form a recess and a loop-shaped protrusion on the other surface side before manufacturing of a chip, it is possible to improve the quality of the chip as compared with the conventional techniques.

Although the invention has been described with respect to specific embodiments for a complete and clear disclosure, the appended claims are not to be thus limited but are to be construed as embodying all modifications and alternative constructions that may occur to one skilled in the art that fairly fall within the basic teaching herein set forth.

What is claimed is:

1. A chip manufacturing method comprising:
preparing a wafer unit, the wafer unit having a protective member fixed to one surface of a wafer and having a recess and a loop-shaped protrusion surrounding the recess provided on the other surface side of the wafer;
processing the wafer and the protective member along a boundary between the recess and the loop-shaped protrusion to separate the recess and the loop-shaped protrusion from each other; and
after separating of the recess and the loop-shaped protrusion, holding the protective member side of the wafer on a holding table and dividing the wafer from the other surface side to manufacture a plurality of chips.

2. The chip manufacturing method according to claim 1, wherein the protective member includes a first sheet in contact with the wafer, a resin layer stacked on the first sheet, and a second sheet stacked on the resin layer.

3. The chip manufacturing method according to claim 1, wherein processing of the wafer and the protective member includes emitting a laser beam.

4. The chip manufacturing method according to claim 1, wherein
preparing of the wafer unit includes
thinning a central region on the other surface side of the wafer to form the recess and the loop-shaped protrusion, and
after the forming of the recess and the loop-shaped protrusion, fixing the protective member to the one surface of the wafer.

5. The chip manufacturing method according to claim 1, wherein
preparing of the wafer unit includes
fixing the protective member to the one surface of the wafer, and
after the fixing of the protective member, thinning a central region on the other surface side of the wafer to form the recess and the loop-shaped protrusion.
